(19) United States
(12) Patent Application Publication
(10) Pub. No.: US 2006/0011926 A1
(43) Pub. Date: Jan. 19, 2006

(54) Light-emitting diode device with resecurable connection

(76) Inventors: Chee Wai Chia, Penang (MY); Kee Yean Ng, Penang (MY); Heng Yow Cheng, Penang (MY)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/892,877

(22) Filed: Jul. 16, 2004

(51) Int. Cl. H01L 33/00; H01L 31/0203

(52) U.S. Cl. 257/79; 257/81; 257/433

(57) ABSTRACT

An LED device includes a scrambler portion, a substrate portion having a light-emitting diode (“LED”) and a substrate layer attached to the LED, an electrical connection between the LED and the substrate layer, and a resecurable connection between the scrambler portion and the substrate layer.

### BACKGROUND OF THE INVENTION

An LED device generally comprises a substrate portion and a scrambler portion. The former typically includes an LED electrically connected to a printed circuit board (“PCB”) substrate, while the latter is often a plastic casing that provides structural integrity to the LED device and a light reflecting cavity in which the LED resides. These two portions have traditionally been secured to each other by a plastic “stake”. Specifically, this connection is achieved by inserting a plastic stake associated with the scrambler portion through a hole in the PCB, and then melting the tip of the plastic stake into a plastic lump to secure the scrambler portion to the substrate portion.

FIG. 1A is a cross-sectional view of a prior art LED device 10 before assembly. An LED 12 is mounted on a substrate portion 14, such as a PCB, and is connected to a substrate layer 16 with an electrical connection 18, such as a bond wire. A scrambler portion 20 includes a reflective cavity 22, and a plastic stake 24 with a tip 26. A through hole 28 in the substrate portion receives the plastic stake 24 when the scrambler portion 20 is assembled to the substrate portion 14.

FIG. 1B is a cross-sectional view of the prior art LED device 10 of FIG. 1A with the scrambler portion 20 assembled to the substrate portion 14. The tip 26 of the plastic stake 24 extends through the substrate portion, and the LED 12 and electrically connection 18 reside within the reflective cavity 22.

FIG. 1C is a cross-sectional view of the prior art LED device 10 shown in FIG. 1B with the scrambler portion secured to the substrate portion. The substrate portion 14 is secured to the scrambler portion 20 by heating the tip 26 of the plastic stake 24 to form a plastic lump 29.

Unfortunately, the prior art plastic stake method is plagued with inherent challenges that render it prone to potential problems and defects. For instance, if the tip of the plastic stake is excessively heated, thermal degradation of the LED device's electronic components, open failures, intensity degradation, burning of the tip of the plastic stake, and/or contamination of the heating element employed to melt the tip may occur. Moreover, the delicate control required by the melting process often results in imperfections in the plastic lump that weaken or destroy its holding strength. Finally, once the plastic lump is broken (either intentionally or unintentionally), the substrate portion and scrambler portion cannot be re-secured by the plastic stake. Rather, a new scrambler portion having a new plastic stake must be sought, as the original scrambler portion is rendered useless.

In light of the above, there is a need for a device and method for securing a substrate portion of an LED device to a scrambler portion that is not fraught with such disadvantages. In addition, there is a need for a resecurable connection between a substrate portion and a scrambler portion; an adjustable securing means for creating a resecurable connection between a substrate portion and a scrambler portion; an LED device having a resecurable connection; and a method for securing a substrate portion to a scrambler portion that is resecurable. This need is met by a resecurable connection between a substrate portion and a scrambler portion; an adjustable securing means for creating a resecurable connection; an LED device having a resecurable connection; a method of constructing an LED device having a resecurable connection; and a method of forming a resecurable connection between a substrate portion and a scrambler portion according to the present invention.

### SUMMARY OF THE INVENTION

According to an embodiment of the present invention, there is provided an LED device that includes a scrambler portion, a substrate portion having a light-emitting diode (“LED”), a substrate layer attached to the LED, an electrical connection between the LED and the substrate layer, and a resecurable connection between the scrambler portion and the substrate layer.

### BRIEF DESCRIPTIONS OF THE DRAWINGS

FIG. 1A is a cross-sectional view of a prior art LED device before assembly.

FIG. 1B is a cross-sectional view of the prior art LED device shown in FIG. 1A with a scrambler portion assembled to a substrate portion.

FIG. 1C is a cross-sectional view of the prior art device shown in FIG. 1B with the scrambler portion secured to the substrate portion.

FIG. 2A is a cross-sectional view of an LED device with an unsecured resecurable connection according to an embodiment of the invention.

FIG. 2B is a cross-sectional view of the LED device f FIG. 2A with a first adjustable securing means (in the form of a first adjustable latch) derived from the scrambler portion and a second adjustable securing means (in the form of a second adjustable latch) derived from the scrambler portion, and showing a first resecurable sub-connection and a second resecurable sub-connection, both securing the scrambler portion to the substrate portion.

FIG. 3 is a cross-sectional close-up view of a portion of the LED device 30 shown in FIG. 2B.

FIG. 4 is a cross-sectional close-up view of another portion of the LED device 30 shown in FIG. 2B.

FIGS. 5A and 5B illustrate the flexibility of the first adjustable securing means.

FIGS. 6A and 6B illustrate the flexibility of the second adjustable securing means.

FIG. 7 shows an embodiment of an LED device having one adjustable securing means in the form of an adjustable latch and a second type of resecurable connection comprised of a second type of securing means to further secure the substrate portion to the scrambler portion.

FIG. 8A shows another embodiment of an LED device 110 before assembly.

FIG. 8B shows the LED device 110 of FIG. 8A after assembly.

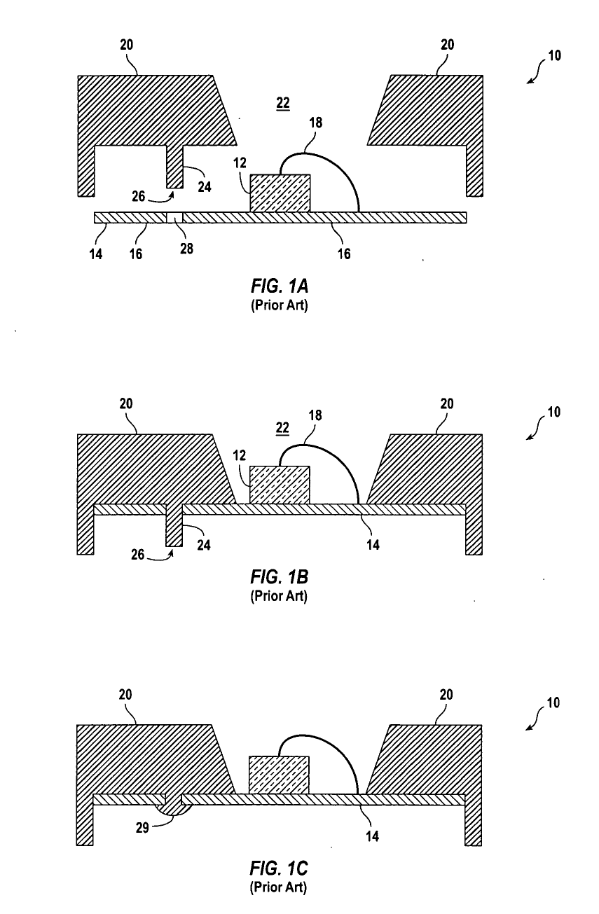

### DETAILED DESCRIPTION

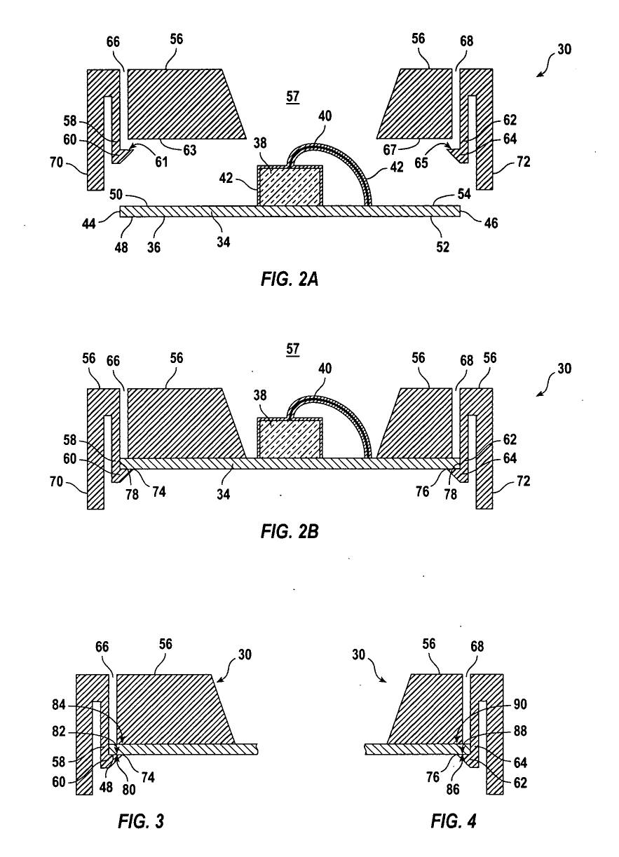

FIG. 2A is a cross-sectional view of an LED device 30 with an unsecured resecurable connection (i.e. before assembly) according to an embodiment of the invention. A substrate portion 34 includes a substrate layer 36; an LED 38 attached to the substrate layer 36; and an electrical connection 40 (of at least one of: gold, aluminium and copper) between the LED 38 and the substrate layer 36. In this embodiment, the dimensions of the substrate layer 36 are technology dependent and can range from very small dimensions (for example a few millimetres) to relatively large sizes (for example tens of centimetres). Moreover, in alternate embodiments, the electrical connection 40 takes other forms, such as two wires, or a direct connection (e.g., via flip chip technology); and others will be readily known to those skilled in the art.

In addition, a protective coating 42 of silicone gel covers the LED 38 and the electrical connection 40 in order to protect them from moisture or any mishandling. Alternatively, an optical grade epoxy encapsulation (not shown) covers the LED 38 and the electrical connection 40 for the same purpose; while other protective options will be readily known to those skilled in the art. Moreover, additional embodiments do not include protection of the LED 38 and the electrical connection 40.

FIG. 2A also shows the substrate layer 36 having a first substrate layer section 44 and a second substrate layer section 46. The first substrate layer section 44 includes a first substrate layer lower section 48 and a first substrate layer upper section 50; while the second substrate layer section 46 includes a second substrate layer lower section 52 and a second substrate layer upper section 54.

In this embodiment, the substrate layer 36 comprises a PCB. However, it will be apparent to those skilled in the art that the substrate layer 36 alternatively comprises other substrates in alternate embodiments; such alternate substances being of at least one of: a ceramic, a molded interconnect device (“MID”), and a flexible circuit.

In a particular embodiment, a scrambler portion 56 comprises polycarbonate (PC) plastic. Alternatively, the scrambler portion 56 comprises one of polycarbonate, and polycarbonate and acrylonitrile/butadiene/styrene (“ABS”), and polybutylene terephthalate, liquid crystal polymer (“LCP”) or polyphtalamide (“PPA”). The dimensions of the scrambler portion are technology, design or application dependent. When the scrambler portion 56 is assembled with the substrate portion 34, the LED 38 resides in a reflective cavity 57.

Moreover, the scrambler portion 56 includes a first adjustable securing means 58 (in the form of a first adjustable latch 60 having a first adjustable latch surface 61 configured to interface with a first scrambler lower section 63) and a second adjustable securing means 62 (in the form of a second adjustable latch 64 having a second adjustable latch surface 65 configured to interface with a second scrambler lower section 67). As used herein, “adjustable” means capable of adjustment. Alternatively, “adjustable” also is meant to include at least flexible (as discussed below); and alternatively is also meant to include both flexible and resilient (as also discussed below).

The first adjustable securing means 58 and the second adjustable securing means 62 are essentially derived from the scrambler portion 56 through a plastic injection molding process. The plastic injection molding process forms a first hollow slot 66 and a second hollow slot 68. The formation of the first adjustable securing means 58, second adjustable securing means 62, and hollow slots 66, 68 will be readily known to those skilled in the art.

The scrambler portion 56 also includes a first protective stake 70 and a second protective stake 72 to protect the first and second adjustable securing means 58, 62 from being unintentionally moved and/or damaged (e.g. as the LED device 30 is typically connected to a circuit (not shown) via connecting conductive pins (also not shown). The formation of, and rationale behind, the first and second protective stakes 70, 72—which are also derived from the scrambler portion 56—will be readily apparent to those skilled in the art. Alternate embodiments do not include the first and second protective stakes 70, 72. The formation of the protective stakes will also be readily apparent to those skilled in the art.

FIG. 2B is a cross-sectional view of the LED device 30 of FIG. 2A with a first adjustable securing means 58 (in the form of a first adjustable latch 60) derived from the scrambler portion 56 and a second adjustable securing means 62 (in the form of a second adjustable latch 64) derived from the scrambler portion 56, and showing a first resecurable sub-connection 74 and a second resecurable sub-connection 76, both securing the scrambler portion 56 to the substrate portion 34. A resecurable connection 78 secures the substrate portion 34 to the scrambler portion 56. The term “resecurable,” as used herein, means capable of being secured, unsecured, and re-secured.

As described below, alternate embodiments use other adjustable securing means that are distinct from, but attached to, an alternate scrambler portion. Moreover, it will be readily apparent to those skilled in the art that there are numerous other ways, using molding technology, to form the first and second adjustable securing means 58, 62. In addition, other forms of the two adjustable securing means will be readily known to those skilled in the art.

FIG. 2B shows the LED 38 and the electrical connection 40 residing in the reflective cavity 57 of the scrambler portion 56. A portion of the light from the LED 38 reflects off the reflective cavity 57. The reflective cavity 57 includes a light reflecting coating of at least one of: silver, aluminium, and nickel. Also, it will be readily understood that other embodiments have a plurality, and even tens or hundreds of light-reflecting cavities.

The first adjustable latch 60 is located at a substantial mid-point on the side of the scrambler portion 56 on which it is located, and the second adjustable latch 64 is located at a substantial mid-point of its respective side of the scrambler portion as well, which supports the substrate portion 34 most effectively. In alternate embodiments, first and second adjustable latches are placed in other locations that will be readily known to those skilled in the art.

Resecurable connection 78 comprises a first resecurable sub-connection 74 and a second resecurable sub-connection 76. However, alternative embodiments have only one resecurable sub-connection, and other alternative embodiments have more than two resecurable sub-connections. In light of strength and costs considerations, some embodiments have four resecurable sub-connections. That said, it will be readily apparent to those skilled in the art than more than four resecurable sub-connections. In fact, alternate embodiments have tens, and even hundreds, of resecurable sub-connections.

FIG. 3 is a cross-sectional close-up view of a portion of the LED device 30 shown in FIG. 2B. The first resecurable sub-connection 74 is secured. The first resecurable sub-connection 74 includes a first adjacency 80 between the first substrate layer lower section 48 and a first adjustable securing means surface 82, the first adjustable securing means surface 82 being a first adjustable latch surface (see FIG. 2A, ref. num. 61); and a second adjacency 84 between the first substrate layer upper section (see FIG. 2A, ref. num. 50) and the first scrambler lower section (see FIG. 2A, ref. num. 63)). The first resecurable sub-connection 74 includes the first substrate layer section of the substrate layer (see FIG. 2A, ref. nums. 44, 36) sandwiched between the scrambler portion 56 and the first adjustable securing means 58.

FIG. 4 is cross-sectional close-up view of another portion of the LED device 30 shown in FIG. 2B. The second resecurable sub-connection 76 includes a third adjacency 86 between the second substrate layer lower section (see FIG. 2A, ref. num. 52) and a second adjustable securing means surface 88 (the second adjustable securing means surface 88 being a second adjustable latch surface (see FIG. 2A, ref. num. 65); and a fourth adjacency 90 between the second substrate layer upper section and the second scrambler lower section (see FIG. 2A, ref. nums. 54, 67). However, it will be readily apparent that the first and second resecurable sub-connections 74, 76 in alternative embodiments do not include some, or any, of these adjacencies 80, 84, 86, 90. The second resecurable sub-connection 76 includes the second substrate layer section of the substrate layer (see FIG. 2A, ref. nums. 46, 36) sandwiched between the scrambler portion 39 and the second adjustable securing means 63. In this regard, only the former applies in embodiments having only one resecurable sub-connection.

In the embodiment shown in FIG. 2B, the first and second adjustable securing means surfaces 82, 88 each respectively have dimensions that are technology, design or application dependent. Generally, the size of the first and second adjustable securing means surfaces 82, 88 depend on the size of the LED device 38 and the number of adjustable latches (e.g. first and second adjustable latches 60, 64) employed (as it will be readily apparent that one, or more than two adjustable latches—even tens and hundreds—are employed in alternate embodiments). On a similar note, increasing the area of the first and second adjustable securing means surfaces 82, 88 (i.e. adjustable latch surface length times adjustable latch surface width) will enhance their respective contact forces and their strength; and, therefore, the overall strength of the first and second resecurable sub-connections 74, 76.

It will be readily apparent to those skilled in the art that there are innumerable shapes of adjustable latches in alternate embodiments. Moreover, it will be readily apparent that the lengths of the first and second adjustable securing means surfaces 82, 88 are technology, design or application dependent. As mentioned above, the first and second securing means 58, 62 (i.e. the first and second adjustable latches 60, 64 in this embodiment) comprise plastic and are, therefore, flexible. “Flexible” meaning that the substrate portion 34 may be placed adjacent to the scrambler portion 56 without causing any undesirable permanent deformations to either the substrate portion 34 and/or the scrambler portion 56 (including the adjustable first and second adjustable latches 60, 64).

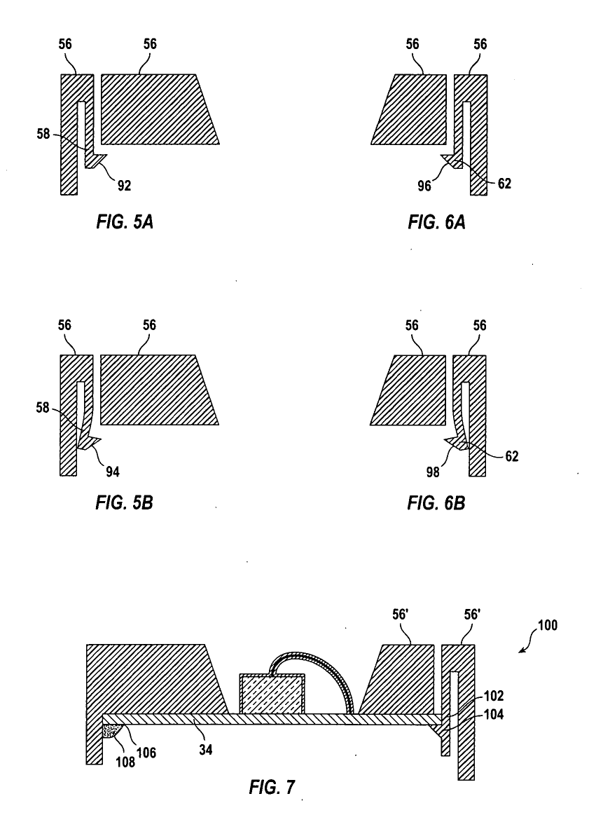

FIGS. 5A and 5B illustrate the flexibility of the first adjustable securing means 58. The first adjustable securing means 58 of the scrambler portion 56 is movable from a first position 92 (shown in FIG. 5A)—its “home position”—to a second position 94 (shown in FIG. 5B). The second position 94 permits the first substrate layer section (see FIG. 2A, ref. num. 44) to be positioned above the first adjustable securing means 58, and the first position 92 allows the first resecurable sub-connection (see FIG. 2B, ref. num. 74) to be secured.

FIGS. 6A and 6B illustrate the flexibility of the second adjustable securing means 62. The second adjustable securing means 62 of the scrambler portion 56 is movable from a third position 96—its “home position”—(shown in FIG. 6A) to a fourth position 98 (shown in FIG. 6B). The fourth position 98 permits the second substrate layer section (see FIG. 2A, ref. num. 46) to be positioned above the second adjustable securing means 62, and the third position 96 allows the second resecurable sub-connection (see FIG. 2B, ref. num. 76) to be secured. In alternate embodiments, only the first adjustable securing means 58 is flexible or only the second adjustable securing means 62 is flexible—but, importantly, such embodiments still allow the substrate portion to be placed adjacent to the scrambler portion without causing any permanent deformations to either.

The first and second adjustable securing means 58, 62 (i.e. the first and second adjustable latches (see FIG. 2B, ref. nums. 60, 64 in this embodiment) are also resilient. “Resilient” meaning that the first adjustable securing means 58 naturally—i.e. without manual assistance—returns to at least substantially the first position 92 from the second position 94, and the second adjustable securing means 62 naturally—i.e. without manual assistance—returns to at least substantially the third position 96 from the fourth position 98.

In further embodiments, the first and second adjustable securing means 58, 62 are one of the following: both flexible but not resilient; both flexible and only one resilient; both flexible and resilient; and, one flexible only and the other resilient only. In embodiments where one or more of the first and second adjustable securing means 58, 62 are not resilient, manual assistance will be needed to position each non-resilient adjustable securing means to its respective “home position”.

More generally, the flexibility and resilience of the first and second adjustable securing means 58, 62 will depend on their design and size. For instance, ones having greater dimensions—and most importantly larger lengths of adjustable latch surfaces, e.g. first and second adjustable latch surfaces 61, 65 shown in FIG. 2A—require greater flexibility vis a vis adjustable latches having smaller latch surface lengths (assuming they are made of similar material).

As shown in FIG. 5B and FIG. 6B, first and second adjustable latches 60, 64 (i.e. the first and second adjustable securing means 58, 62) are respectively moved to their second and fourth positions 94, 98 to unsecure the resecurable connection (see FIG. 2B, ref. num. 78); thereby allowing the separation of the substrate portion (not shown in FIGS. 5B and 6B) from the scrambler portion 56. In alternate embodiments, it is sufficient that either adjustable latch, e.g. the first adjustable latch 60, is positioned in the second position 94 or the second adjustable latch 64 is positioned in the fourth position 98 to unsecure the resecurable connection.

The resecurable connection is also resecurable. The resecuring process is the same as discussed generally above with regard to the first and second adjustable securing means 58, 62 (i.e. the first and second adjustable latches 60, 64). As mentioned above, other embodiments have one adjustable latch, and alternate embodiments have more than two adjustable latches.

FIG. 7 shows an embodiment of an LED device 100 having one adjustable securing means 102 in the form of an adjustable latch 104 and a second type of resecurable connection 106 comprised of a second type of securing means 108 (such as an adhesive or glue) to further secure the substrate portion 34 to the scrambler portion 56′. Generally, more adjustable latches provide a stronger connection between the substrate portion 34 and the scrambler portion 56′. That said, in light of cost considerations, four adjustable latches often provide a strong and cost-effective connection in many instances.

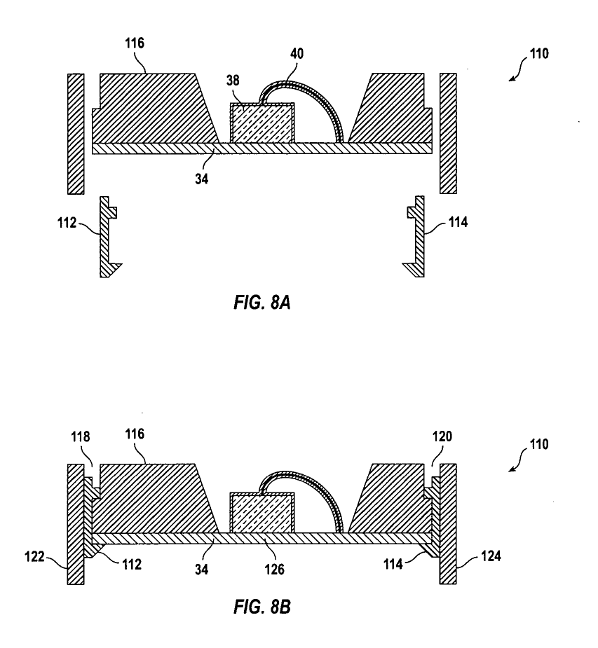

FIG. 8A shows another embodiment of an LED device 110 before assembly. The LED device 110 has first and second adjustable securing means 112, 114, a scrambler portion 116, and a substrate portion 34 with an LED 38 and an electrical connection 40.

FIG. 8B shows the LED device 110 of FIG. 8A after assembly. The first and second adjustable securing means 112, 114 attach the substrate portion 34 to the scrambler portion 116. Comparing FIG. 8B to FIG. 2B, the two embodiments are similar except that the first and second adjustable securing means 112, 114 in the embodiment of FIG. 8B are distinct from, and attached to, the scrambler portion 116.

Molded hollow slots 118, 120 in the embodiment 110 shown in FIG. 8B have a slightly different shape than the first and second hollow slots 66, 68 in the embodiment shown in FIG. 2B to accommodate the shape of the first and second adjustable securing means 112, 114. The molded hollow slots 118, 120 are shaped in this way to allow the first and second adjustable securing means 112, 114 to be inserted into the scrambler portion 116 between the substrate portion 34 and the protective stakes 122, 124 to form a connection between the scrambler portion 116 and a substrate layer 126. The formation of these adjustable securing means will be readily known to those skilled in the art.

The attachment of the first and second adjustable securing means 112, 114 to the scrambler portion 116 is accomplished by manual insertion or mechanically pressed by jigs, fixtures or machines.

Although the invention has been described with reference to specific examples, it will be appreciated by those skilled in the art that it may be embodied in many other forms.

1. An LED device comprising:
a scrambler portion;
a substrate portion including:
(a) an LED;
(b) a substrate layer attached to the LED;
an electrical connection between the LED and the substrate layer; and
a resecurable connection between the scrambler portion and the substrate layer.

2. An LED device according to claim 1 wherein the resecurable connection includes a first resecurable sub-connection having a first adjustable securing means.

3. An LED device according to claim 2 wherein:
the substrate layer has a first substrate layer section; and
the first resecurable sub-connection includes the first substrate layer section sandwiched between the scrambler portion and the first adjustable securing means.

4. An LED device according to claim 3 wherein:
the scrambler portion has a first scrambler lower section;
the first substrate layer section includes a first substrate layer lower section and a first substrate layer upper section; and
the first resecurable sub-connection includes:
(a) a first adjacency between the first substrate layer lower section and a first adjustable securing means surface of the first adjustable securing means; and
(b) a second adjacency between the first substrate layer upper section and the first scrambler lower section.

5. An LED device according to claim 3 wherein the first adjustable securing means is flexible such that the first adjustable securing means adopts a first position and a second position.

6. An LED device according to claim 5 wherein the first adjustable securing means is resilient such that the first adjustable securing means naturally returns to at least substantially the first position from the second position.

7. An LED device according to claim 2 wherein the first adjustable securing means is distinct from, and attached to, the scrambler portion.

8. An LED device according to claim 2 wherein the first adjustable securing means is essentially derived from the scrambler portion.

9. An LED device according to claim 2 wherein the first adjustable securing means is a first adjustable latch.

10. An LED device according to claim 1 wherein the resecurable connection further includes a second resecurable sub-connection having a second adjustable securing means.

11. An LED device according to claim 10 wherein the second adjustable securing means is distinct from, and attached to, the scrambler portion.

12. An LED device according to claim 10 wherein the second adjustable securing means is essentially derived from the scrambler portion.

13. An LED device according to claim 11 wherein the first and second adjustable securing means are adjustable latches.

14. An LED device according to claim 12 wherein the first and second adjustable securing means are adjustable latches.

15. An LED device according to claim 1 wherein the LED device further includes a second resecurable connection.

16. An LED device according to claim 15 wherein the second type of resecurable connection is comprised of a second type of securing means.

17. An LED device according to claim 16 wherein the second type of securing means is at least one of a glue, and an adhesive.

18. A resecurable connection between a scrambler portion and a substrate portion of an LED device including an adjustable securing means that secures the substrate portion to the scrambler portion.

19. A method for constructing an LED device comprising:
forming a resecurable connection between a scrambler portion and a substrate portion;
wherein the substrate portion at least includes:
(a) an LED;
(b) a substrate layer attached to the LED; and
(c) an electrical connection between the LED and the substrate layer.

20. A method for constructing an LED device according to claim 19 wherein:
the resecurable connection at least includes a first resecurable sub-connection;
the first resecurable connection includes a first adjustable securing means;
the substrate layer has a first substrate layer section; and
the forming of the first resecurable sub-connection includes sandwiching the first substrate layer section between the scrambler portion and the first adjustable securing means.

21. A method of forming a resecurable connection between a scrambler portion and a substrate portion including repositioning a first adjustable securing means from a second position to a first position.

22. A method of forming a resecurable connection according to claim 21 wherein:
the repositioning is accomplished in at least one of the following ways: manually, and by manually positioning the adjustable resecuring means to the second position so that a resiliency associated with the first adjustable securing means accomplishes the repositioning.
